(19) United States
(12) Patent Application Publication
(10) Pub. No.: US 2015/0159265 A1
(43) Pub. Date: Jun. 11, 2015

(54) METAL CHALCOGENIDE THIN FILM AND PREPARING METHOD THEREOF

(71) Applicant: Research & Business Foundation SUNGKYUNKWAN UNIVERSITY, Suwon-si (KR)

(72) Inventors: Tae Sung KIM, Seoul (KR); Chi Sung AHN, Suwon-si (KR); Changgu LEE, Seoul (KR); Hyeongu KIM, Ansan-si (KR); Jinhwan LEE, Seongnam-si (KR); Girish ARABALE, Suwon-si (KR)

(73) Assignee: Research & Business Foundation SUNGKYUNKWAN UNIVERSITY, Suwon-si (KR)

(21) Appl. No.: 14/565,885

(22) Filed: Dec. 10, 2014

(30) Foreign Application Priority Data
Dec. 10, 2013 (KR) 10-2013-0152849

(51) Int. Cl. C23C 14/54; C23C 14/06; C23C 14/08; C01G 39/06

(52) U.S. Cl. CPC C23C 14/542; C01G 39/06; C23C 14/0623; C23C 14/08

(57) ABSTRACT

Provided herein is a metal chalcogenide thin film and a method for preparing the metal chalcogenide thin film, the method including forming a metal layer on a substrate; and forming a metal chalcogenide thin film by inserting the substrate into a chamber for low temperature vapor deposition, injecting a gas containing chalcogen atoms and an argon gas into the chamber, generating a plasma such that chalcogen atoms decomposed by the plasma chemically combine with metal atoms constituting the metal layer to form the metal chalcogenide thin film.

### CROSS-REFERENCE TO RELATED APPLICATION

This application claims the benefit of priority under 35 U.S.C. § 119(a) of Korean Patent Application No. 10-2013-0152849, filed on Dec. 10, 2013, in the Korean Intellectual Property Office, the entire disclosure of which is incorporated herein by reference for all purposes.

1. Field

The present invention relates to a metal chalcogenide thin film and a preparing method thereof, and more particularly, to a method for preparing a metal chalcogenide thin film on a plastic substrate using a low temperature vapor deposition method.

2. Background

Generally, amorphous silicon (a-Si), polycrystalline silicone (LPTS), and oxide semiconductor (IGZO) are semiconductor materials mostly used in thin film transistors that form displays such as LCD TVs.

Especially, amorphous silicon (a-Si) is most widely used thanks to its relatively high manufacture reliability. However, amorphous silicon (a-Si) has a disadvantage: low electric charge mobility. Thus, amorphous silicon is not suitable for high performance displays.

Polycrystalline silicone (LPTS) has excellent semiconductor performance, but its production costs are high, and it is difficult to use LPTS in materials that need bending.

Oxide semiconductor (IGZO) has low production costs per unit, but it also has a problem of poor performance and low manufacture reliability compared to polycrystalline silicone (LPTS).

In order to overcome these problems, a technology was proposed that uses metal chalcogenide thin films having a broad band gap and the potential of providing short wavelength optical emission.

Metal chalcogenide materials are materials that include chalcogen atoms and one or more additional atoms that generally act to change electrical or structural characteristics.

Hereinafter, molybdenum disulfide (MoS₂) in the metal chalcogenide thin film will be exemplified in detail hereinafter.

In a bulk state, molybdenum disulfide (MoS₂) has a indirect band-gap of 1.2 eV, and thus shows similar electronic characteristics as crystalline silicon. Furthermore, it has been proved that molybdenum disulfide (MoS2) has a charge mobility of about 100 cm²/Vs even where its thickness is approximately 10 nm. Another advantage of molybdenum disulfide (MoS₂) is that it provides an ample on/off ratio range for performing switching.

Furthermore, molybdenum disulfide (MoS₂) shows good properties compared to other materials even with an extremely small thickness (10 nm or less), and thus has a high transparency (about 80% at a thickness of 5 nm) and high flexibility.

Molybdenum disulfide (MoS2) has excellent properties compared to other materials that are currently being developed, and thus it has an advantage of possibility of application to TVs togehter with graphene.

To form a molybdenum disulfide (MoS₂) thin film, there is a prior art of decomposing sulfur at a high temperature of 600° C. or above on a silicon substrate (SiO₂ or Si) coated with silicon oxide in a CVD (Chemical Vapor Deposition) method (thermolysis).

However, in this method, it is almost impossible to compound a molybdenum disulfide (MoS₂) thin film directly on a glass or plastic substrate due to the high temperature condition. The method has to go through a transcribing process if it is to prepare a device on a substrate having a low melting point such as glass or plastic.

However, such a transcribing process leads to problems such as films being torn, significant deterioration of quality, and increase of processing costs.

### SUMMARY

A purpose of the present disclosure is to resolve the aforementioned problems of prior art, that is to provide a metal chalcogenide thin film and a method for preparing a metal chalcogenide thin film directly on a substrate having a low melting point such as plastic in in-situ method using a low temperature vapor deposition method (PECVD).

Another purpose is to provide a metal chalcogenide thin film where an additional drying process is unnecessary and a method for preparing the same, as the metal chalcogenide thin film is crystallized right after it is formed.

Another purpose is to provide a metal chalcogenide thin film where the thin film may be formed even without an additional transcribing process and a method for preparing the same, as the metal chalcogenide thin film is formed directly on the substrate.

Another purpose is to provide a metal chalcogenide thin film capable of maximizing electrical/physical characteristics, and of guaranteeing a high uniformity and reliability and a method for preparing the same, as the metal chalcogenide thin film is formed directly on the substrate.

According to an exemplary embodiment of the present invention, there is provided a method for preparing a metal chalcogenide thin film, the method including forming a metal layer on a substrate; and forming a metal chalcogenide thin film by inserting the substrate into a chamber for low temperature vapor deposition, injecting a gas containing chalcogen atoms and an argon gas into the chamber, generating a plasma such that chalcogen atoms decomposed by the plasma chemically combine with metal atoms constituting the metal layer to form the metal chalcogenide thin film.

The method may further include removing an oxide film by injecting hydrogen at a plasma state into the chamber after inserting of the substrate into the chamber but before the forming of a thin film so as to remove the oxide film formed on a surface of the substrate.

The method may further include removing foreign substance from air inside the chamber by further injecting argon gas for a certain period of time before the removing of the oxide film.

The metal chalcogenide thin film may have a plate structure including at least one layer.

Each layer forming the metal chalcogenide thin film may be detached individually.

A thickness of each layer may be adjusted by adjusting a flow rate of the gas containing chalcogen atoms being injected into the chamber, by controlling a temperature inside the chamber, or by adjusting a thickness of the metal layer.

The temperature inside the chamber may be 50° C. to 700° C.

The temperature inside the chamber may be 100° C. to 500° C.

The metal layer may be formed using at least one of a sputtering method, E-beam evaporator method, thermal evaporation method, ion cluster beam, and pulsed laser deposition (PLD) method.

The metal layer may be formed after oxidizing the substrate in a in a wet or dry process.

The metal chalcogenide thin film may be MaXb, M being Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb or Po; X being S, Se or Te; and a and b being an integer between 1 to 3.

The metal layer may be at least one of Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb and Po.

The gas containing chalcogen atoms may be at least one of S₂, Se₂, Te₂, H₂S, H₂Se and H₂Te.

The substrate may be at least one of Si, SiO₂, Ge, GaN, AlN, GaP, InP, GaAs, SiC, Al₂O₃, LiAlO₃, MgO, glass, quartz, sapphire, graphite, and graphene.

According to the present disclosure, there is provided a metal chalcogenide thin film and a method for preparing a metal chalcogenide thin film directly on a substrate having a low melting point such as plastic in in-situ method using a low temperature vapor deposition method (PECVD).

Furthermore, there is provided a metal chalcogenide thin film where an additional drying process is unnecessary and a method for preparing the same, as the metal chalcogenide thin film is crystallized right after it is formed.

Furthermore, there is provided a metal chalcogenide thin film where the thin film may be formed even without an additional transcribing process and a method for preparing the same, as the metal chalcogenide thin film is formed directly on the substrate.

Furthermore, there is provided a metal chalcogenide thin film capable of maximizing electrical/physical characteristics, and of guaranteeing a high uniformity and reliability and a method for preparing the same, as the metal chalcogenide thin film is formed directly on the substrate.

### BRIEF DESCRIPTION OF THE DRAWINGS

FIG. 1 is a flowchart of a method for preparing a metal chalcogenide thin film according to an embodiment of the present disclosure;

FIG. 2 is a flowchart of a method for preparing a molybdenum disulfide thin film according to an embodiment of the present disclosure;

FIGS. 3 to 5 are process diagrams for each flow of FIG. 2;

FIG. 6 illustrates Reference Raman data;

FIG. 7 illustrates Raman data according to embodiment 1; and

FIG. 8 illustrates Raman data according to embodiment 2.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

Furthermore, in the various embodiments of the present disclosure, components of the same structure use the same reference numerals, and thus the components will be explained in a first embodiment, and only components different from the first embodiment will be explained in other embodiments.

Hereinafter, a method for preparing a metal chalcogenide thin film according to an embodiment of the present disclosure will be explained in detail with reference to the drawings attached.

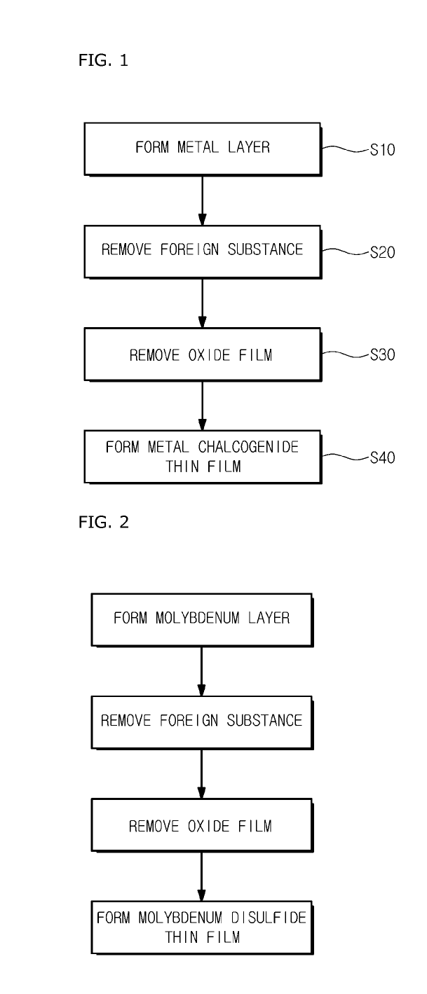

FIG. 1 is a flowchart of a method for preparing a metal chalcogenide thin film according to an embodiment of the present disclosure. Referring to FIG. 1, the method for preparing a metal chalcogenide thin film according to the embodiment of the present disclosure includes forming a metal layer (S10), removing foreign substance (S20), removing an oxide film (S30), and forming a thin film (S40).

Specifically, first of all, inside a predetermined chamber, a substrate is prepared that includes a silicon oxide layer (SiO₂) of a certain thickness formed through a wet or dry process from a base material including silicon (Si) and the like.

The substrate is prepared such that it includes one of Si, SiO₂, Ge, GaN, AlN, GaP, InP, GaAs, SiC, Al₂O₃, LiAlO₃, MgO, glass, quartz, sapphire, graphite, and graphene. The substrate may desirably be PEN (Poly Ethylene Naphthalate) or PET (Poly Ethylene Terephthalate) from which it used to be difficult to form a thin film in a in-situ method of prior art due to their relatively low melting points. The substrate may be prepared to have a flexible form when necessary.

Furthermore, at the forming of a metal layer (S10), a metal layer is formed on the substrate using one of a sputtering method, E-beam evaporator method, thermal evaporation method, ion cluster beam, and pulsed laser deposition method.

Herein, the metal layer may be at least one of Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb and Po.

Furthermore, a thickness of the metal chalcogenide thin film that grows may vary depending on a thickness of the metal layer.

Then, a chamber is prepared that can be used in a Plasma Enhanced Chemical Vaporation Deposition (PECVD) method, Argon (Ar) gas is injected therein, and a substrate where a metal layer is formed is inserted therein.

It is desirable to inject the Argon (Ar) gas into the chamber before inserting the substrate inside the chamber.

Herein, at the removing of foreign substance (S20), it is desirable to further inject the Argon (Ar) gas into the chamber in about 5 to 10 minutes after inserting the substrate inside the chamber. By the Argon gas being injected after the substrate is inserted, foreign substance in the air inside the chamber may be removed.

Then, at the removing of an oxide film (S30), hydrogen molecules (H2) are injected into the chamber so as to remove the oxide film generated on the substrate where a metal layer is formed. Herein, the hydrogen molecules (H₂) are injected in a plasma state. As the hydrogen molecules chemically react with oxygen molecules and thus are substituted to water, the oxide film formed on the substrate surface can be removed.

Furthermore, at the forming of a thin film (S40), a gas containing chalcogen atoms and Argon gas are mixed in a certain ratio and then injected inside the chamber through a distributor, and plasma is generated.

In the present disclosure, forming of a thin film may be realized at a lower temperature than in prior art, and more specifically, the temperature inside the chamber may be 50° C. to 700° C. in one embodiment, 50° C. to 500° C. in another embodiment, 50° C. to 300° C. in another embodiment, 100° C. to 300° C. in another embodiment, and 150° C. to 300° C. in another embodiment.

The plasma decomposes the gas containing chalcogen atoms existing inside the chamber into chalcogen atoms, and the decomposed chalcogen atoms chemically combine with metal atoms constituting the metal layer to form a metal chalcogenide thin film.

Herein, the gas containing chalcogen atoms is at least one of S₂, Se₂, Te₂, H₂S, H₂Se and H₂Te.

Furthermore, the metal chalcogenide thin film formed is MaXb, wherein M is Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb or Po; X is S, Se, or Te; and a and b are integers between 1 to 3.

The metal chalcogenide thin film formed as aforementioned has a plate structure made of at least one layer.

A thickness of each layer may be adjusted by adjusting a flow rate of the gas containing chalcogenide atoms being injected inside the chamber, controlling the temperature inside the chamber, or adjusting the thickness of the metal layer.

In this method, it is possible to form a metal chalcogenide thin film even at a low temperature of 50° C. to 700° C., and thus an additional detaching process may become unnecessary. Furthermore, it is possible to perform deposition while adjusting the thickness of each layer that forms the thin film even at low temperatures.

Furthermore, by forming a metal chalcogenide thin film directly on a plastic material substrate at a low temperature as aforementioned, an additional transcribing process becomes unnecessary.

Furthermore, since the metal chalcogenide thin film is crystallized at the same as it is formed, an additional drying process becomes unnecessary.

Accordingly, it is possible to maximize the electrical/physical characteristics of the metal chalcogenide thin film, and guarantee a high degree of uniformity and reliability.

### Embodiment

FIG. 2 is a flowchart of a method for preparing a molybdenum disulfide thin film according to an embodiment of the present disclosure. Referring to FIG. 2, the method for preparing a molybdenum disulfide thin film according to the embodiment of the present disclosure includes forming a molybdenum layer, removing an oxide film, and forming a thin film.

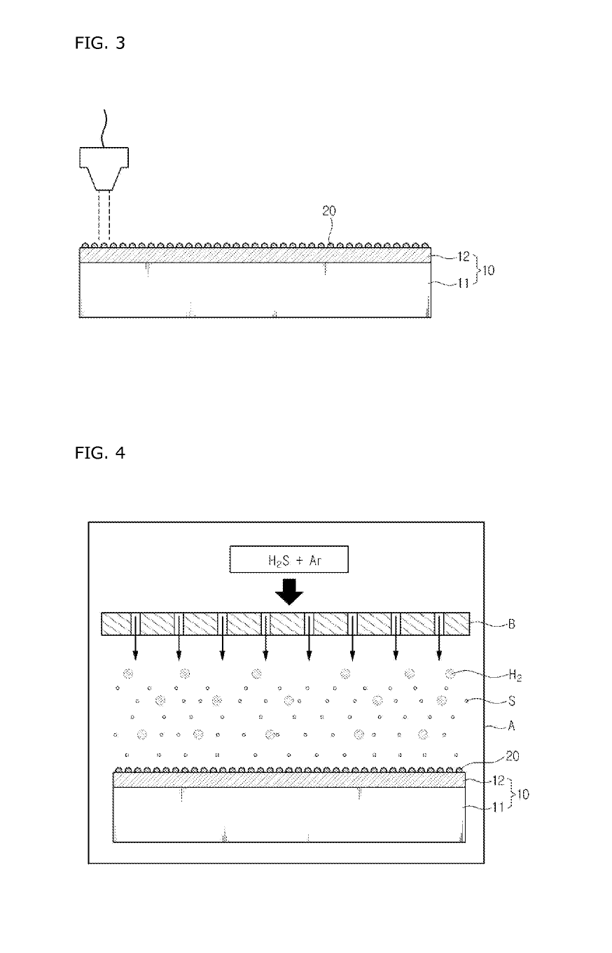

First of all, as illustrated in FIG. 3, a substrate 10 is prepared that includes a silicon oxide layer 12 (SiO₂) of a certain thickness formed through a wet or dry process from a base material including silicon (Si) and the like.

The substrate 10 is made of glass or plastic. Otherwise, it may be made of to have a flexible form when necessary.

A molybdenum layer 20 is formed by evaporating molybdenum on the substrate 10 using a thin film depositing equipment such as an E-beam evaporator and the like.

Herein, a thickness of the molybdenum disulfide thin film 30 that grows may vary depending on a thickness of the molybdenum layer 20.

Then, a chamber is prepared that can be used in a Plasma Enhanced Chemical Vaporation Deposition (PECVD) method, Argon (Ar) gas is injected therein, and a substrate where a molybdenum layer 20 is formed is inserted therein.

Herein, it is desirable to inject a certain amount of Argon gas into the chamber before inserting the substrate 10 into the chamber, and to further inject the Argon (Ar) gas into the chamber in about 5 to 10 minutes after inserting the substrate 10 inside the chamber. By the Argon gas being injected after the substrate 10 is inserted, foreign substance in the air inside the chamber may be removed.

Then, at the removing of an oxide film, hydrogen molecules (H₂) are injected into the chamber so as to remove the oxide film generated on the substrate 10 where a molybdenum layer 20 is formed. As the hydrogen molecules chemically react with oxygen molecules and thus are substituted to water, the oxide film formed on the substrate surface 10 can be removed.

Furthermore, as illustrated in FIG. 4, hydrogen sulfide gas and Argon gas are mixed in a certain ratio and then injected inside the chamber through a distributor, and plasma is generated.

Herein, the ratio of the hydrogen sulfide gas to the Argon gas may be 1:0.5 to 1:5.

The plasma decomposes the hydrogen sulfide gas existing inside the chamber into hydrogen molecules (H₂) and sulfur molecules (S), and the decomposed sulfur molecules (S) chemically combine with molybdenum molecules (Mo) constituting the molybdenum layer 20 to form a molybdenum disulfide thin film 30.

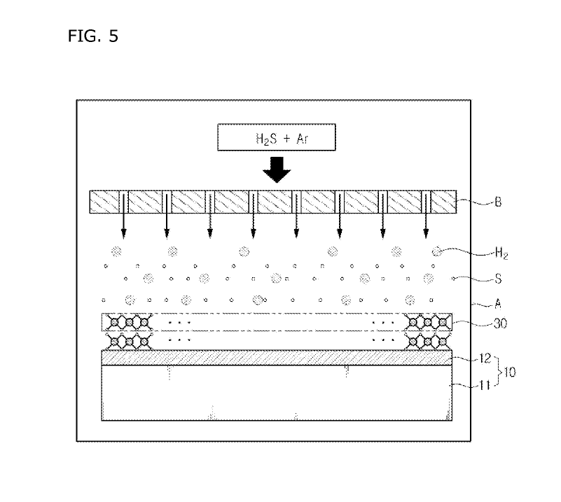

The molybdenum disulfide thin film 30 formed as aforementioned has a plate structure made of at least one layer as illustrated in FIG. 5.

Herein, after the molybdenum disulfide thin film 30 is finally completed, each layer may be detached individually.

Meanwhile, a thickness of each layer of the molybdenum disulfide thin film 30 may be adjusted by adjusting a flow rate of the sulfide gas being injected inside the chamber, controlling the temperature inside the chamber, or adjusting the thickness of the metal layer.

In this method, deposition may be performed while adjusting a thickness of each layer even when the temperature inside the chamber is as low as 50° C. to 700° C., and desirably 300° C. or less.

### TEXT EXAMPLES

### Text example 1

As a specific example of a metal chalcogenide thin film, a molybdenum disulfide thin film is formed in the following method.

First of all, a silicon substrate (Si) is prepared, and a silicon oxide (SiO₂) of a thickness of 300 nm is formed on a top of the substrate. Then, a molybdenum layer is formed to have a thickness of 1 nm using an E-beam evaporator, and then the molybdenum layer is cut in samples having a size of 1×1 cm².

A certain amount of Argon gas is injected inside a chamber for low temperature vapor deposition, the sample is inserted into the chamber, and the Argon gas is injected for about 10 minutes so as to remove foreign substance in the air inside the chamber.

Furthermore, hydrogen molecules (H₂) are injected into the chamber so as to remove the oxide film formed on a surface of the sample. Herein, the hydrogen molecules (H₂) are injected in a plasma state. Then, the hydrogen sulfide (H₂S) and Argon gas (Ar) are mixed in a ratio of 1:5, and then the mixture is injected for about 30 to 120 minutes, and a plasma is generated. Herein, the temperature inside the chamber is maintained to 300° C.

On the sample surface, a plate-structured molybdenum disulfide thin film having a plurality of layers is formed by the plasma.

### Text example 2

As a specific example of a metal chalcogenide thin film, a molybdenum disulfide thin film is formed in the following method.

First of all, on a commercialized polyimide substrate, a molybdenum layer is formed to have a thickness of 1 nm using an E-beam evaporator, and then the molybdenum layer is cut in samples having a size of 1×1 cm².

A certain amount of Argon gas is injected inside a chamber for low temperature vapor deposition, the sample is inserted into the chamber, and the Argon gas is injected for about 10 minutes so as to remove foreign substance in the air inside the chamber.

Furthermore, hydrogen molecules (H₂) are injected into the chamber so as to remove the oxide film formed on a surface of the sample. Herein, the hydrogen molecules (H₂) are injected in a plasma state. Then, the hydrogen sulfide (H₂S) and Argon gas (Ar) are mixed in a ratio of 1:1, and then the mixture is injected for about 60 minutes, and a plasma is generated. Herein, the temperature inside the chamber is maintained to 150° C. or 300° C.

On the sample surface, a plate-structured molybdenum disulfide thin film having a plurality of layers is formed by the plasma.

Crystallization of the molybdenum disulfide thin film may observed through a Raman spectroscopy.

Generally, a Raman peak has a total of 5 types of active modes, of which E22g, E1g, E12g, and A1g are Raman active modes, and the remaining one, E1y is an IR-active mode.

Herein, the molybdenum disulfide thin film shows two types of active modes: E12g and A1g, and thus these may be regarded as essential characteristics. Therefore, the number of layers of the molybdenum disulfide thin film may be checked by measuring a peak distance of E12g and A1g.

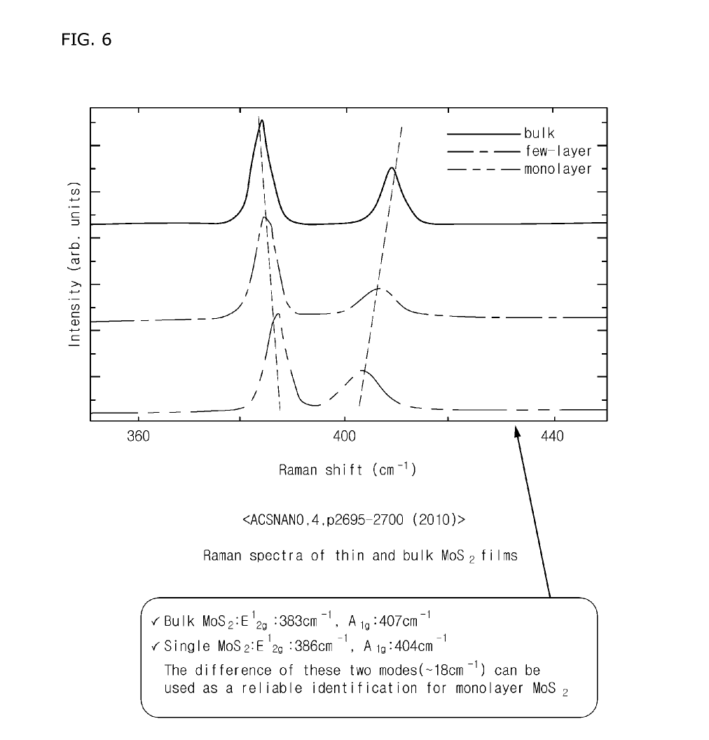

FIG. 6 is a Reference Raman data disclosed in ACSNANO 4, FIG. 7 is Raman data according to test example 1. Referring to FIG. 6, a thickness of one layer of the molybdenum disulfide thin film is 0.68 nm, and the distance between E12g (left peak) and A1g (right peak) increases from single layer towards a bulk layer of the molybdenum disulfide thin film.

In comparison to the aforementioned, in Raman data of FIG. 7 according to the text example 1, E12g (left peak) and A1g (right peak) are 385, 407 when the process time is 30 minutes, and 383, 405, when the process time is 120 minutes.

Based on the aforementioned values, it can be observed that a molybdenum disulfide thin film of about 3˜5 layers is formed per each processing time.

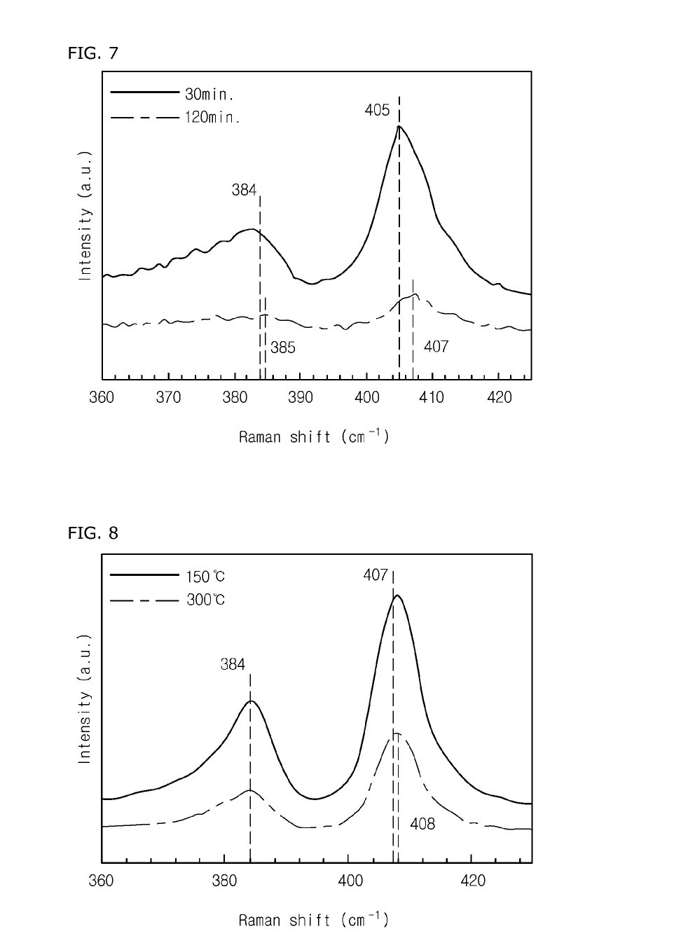

FIG. 8 is Raman data according to text example 2. Referring to FIG. 8, E12g (left peak) and A1g (right peak) are 384, 407˜408.

Based on the aforementioned results, it can be observed that a molybdenum disulfide thin film is formed, and that a molybdenum disulfide thin film of about 3˜5 layers is formed.

While this invention has been described in connection with what is presently considered to be practical embodiments, it is to be understood that the invention is not limited to the disclosed exemplary embodiments, but, on the contrary, is intended to cover various modifications and equivalent arrangements included within the spirit and scope of the appended claims. Therefore, the aforementioned exemplary embodiments should be understood to be exemplary but not limiting the present invention in any way.

### Reference Numerals

10 : SUBSTRATE
11 : BASE MATERIAL
12 : SILICON OXIDE LAYER
20 : MOLYBDENUM LAYER
30 : MOLYBDENUM DISULFIDE THIN FILM

What is claimed is:

1. A method for preparing a metal chalcogenide thin film, the method comprising:
forming a metal layer on a substrate; and
forming a metal chalcogenide thin film by inserting the substrate into a chamber for low temperature vapor deposition, injecting a gas containing chalcogen atoms and an argon gas into the chamber, generating a plasma such that chalcogen atoms decomposed by the plasma chemically combine with metal atoms constituting the metal layer to form the metal chalcogenide thin film.

2. The method according to claim 1,
further comprising removing an oxide film by injecting hydrogen at a plasma state into the chamber after inserting of the substrate into the chamber but before the forming of a thin film so as to remove the oxide film formed on a surface of the substrate.

3. The method according to claim 2,
further comprising removing foreign substance from air inside the chamber by further injecting argon gas for a certain period of time before the removing of the oxide film.

4. The method according to claim 1,
wherein the metal chalcogenide thin film has a plate structure including at least one layer.

5. The method according to claim 4,
wherein each layer forming the metal chalcogenide thin film may be detached individually.

6. The method according to claim 5,
wherein a thickness of each layer may be adjusted by adjusting a flow rate of the gas containing chalcogen atoms being injected into the chamber, by controlling a temperature inside the chamber, or by adjusting a thickness of the metal layer.

7. The method according to claim 1,
wherein the temperature inside the chamber is 50° C. to 700° C.

8. The method according to claim 1,
wherein the temperature inside the chamber is 100° C. to 500° C.

9. The method according to claim 1,
wherein the metal layer is formed using at least one of a sputtering method, E-beam evaporator method, thermal evaporation method, ion cluster beam, and pulsed laser deposition (PLD) method.

10. The method according to claim 1,
wherein the metal layer is formed after oxidizing the substrate in a in a wet or dry process.

11. The method according to claim 1,
wherein the metal chalcogenide thin film is MaXb, M being Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb or Po; X being S, Se or Te; and a and b being an integer between 1 to 3.

12. The method according to claim 1,
wherein the metal layer is at least one of Mo, W, Bi, Mg, Al, Si, Ca, Sc, Ti, V, Cr, Mn, Fe, Co, Ni, Cu, Zn, Ga, Ge, Sr, Y, Zr, Nb, Tc, Ru, Rh, Pd, Ag, Cd, In Sn, Sb, Ba, La, Hf, Ta, Re, Os, Ir, Pt, Au, Hg, TI, Pb and Po.

13. The method according to claim 1,
wherein the gas containing chalcogen atoms is at least one of S₂, Se₂, Te₂, H₂S, H₂Se and H₂Te.

14. The method according to claim 1,
wherein the substrate is at least one of Si, SiO₂, Ge, GaN, AlN, GaP, InP, GaAs, SiC, Al₂O₃, LiAlO₃, MgO, glass, quartz, sapphire, graphite, and graphene.

15. A metal chalcogenide thin film prepared by a method of claim 1.
